(19) United States
(12) Patent Application Publication
(10) Pub. No.: US 2026/0252746 A1
(43) Pub. Date: Aug. 27, 2026

(54) TURKISH COFFEE MAKERS INTEGRATED WITH ARTIFICIAL INTELLIGENCE BASED TASSEOGRAPHY SYSTEM

(71) Applicant: Denet Cem Tezel, Ankara (TR)

(72) Inventor: Denet Cem Tezel, Ankara (TR)

(21) Appl. No.: 19/321,228

(22) Filed: Sep. 7, 2025

Related U.S. Application Data
(63) Continuation of application No. PCT/TR2023/050235, filed on Mar. 9, 2023.

(51) Int. Cl. G06F 30/12; G06F 40/58; G06K 7/14; G06T 17/20; G06V 10/74; G06V 10/94; G06V 20/68; G06V 40/16

(52) U.S. Cl. CPC G06F 30/12; G06F 40/58; G06K 7/1417; G06T 17/20; G06V 10/74; G06V 10/95; G06V 20/68; G06V 40/166

(57) ABSTRACT

A system and method for providing Turkish coffee tasseography-based fortune-telling using artificial intelligence. The system comprises a Turkish coffee maker integrated with a circuit board configured to record preparation data, custom-designed coffee cups with unique machine- readable codes, and a server connected to a mobile device. The server receives images of the coffee grounds, verifies authenticity using the code, generates a three-dimensional digital model of the coffee grounds, flattens the model using stereographic projection, detects symbols and patterns with computer vision, and produces a personalized fortune-telling text using natural language processing. The text is delivered to the user via a chatbot interface and may be translated into multiple languages.

### BACKGROUND OF THE INVENTION

### FIELD OF THE INVENTION

The present invention relates to beverage appliances, artificial intelligence, and digital image processing, and more specifically to Turkish coffee makers integrated with an artificial intelligence system for tasseography (coffee-ground fortune-telling).

### DESCRIPTION OF RELATED ART

Turkish coffee is one of the world's oldest brewing methods and is culturally recognized as an Intangible Cultural Heritage of Humanity by UNESCO. Fortune-telling based on coffee grounds (tasseography) is a longstanding tradition in Turkish culture. However, access to fortune-telling is limited to skilled individuals, often requiring fees, personal availability, or language proficiency.

Recent attempts to digitize tasseography include mobile applications that connect users with human fortune-tellers. These approaches are inconsistent, lack standardized quality, and are prone to fraudulent practices. Furthermore, tourists and non-Turkish speakers often face difficulty accessing authentic tasseography services outside of Turkey.

Accordingly, there exists a need for a standardized, automated, and accessible system for delivering coffee fortune-telling services without reliance on human fortune-tellers.

### SUMMARY OF THE INVENTION

The invention provides a comprehensive system, method, and computer-readable medium for tasseography-based fortune-telling using Turkish coffee. The system includes:

A Turkish coffee maker with an integrated circuit board to record preparation events and transmit data.

Custom coffee cups with unique QR codes or other machine-readable identifiers.

A server incorporating modules for image verification, computer vision, stereographic projection, and natural language processing.

A mobile device application (iOS, Android, or web) providing user interaction via chatbot interface.

The invention standardizes coffee fortune-telling, ensures authenticity of preparation, and generates a personalized fortune text derived from detected symbols, shapes, and patterns within the coffee grounds. The invention further enhances user experience by incorporating demographic and emotional analysis, multi-language translation, and data association with user profiles.

### BRIEF DESCRIPTION OF THE DRAWINGS

FIG. 1: Workflow diagram of the system.

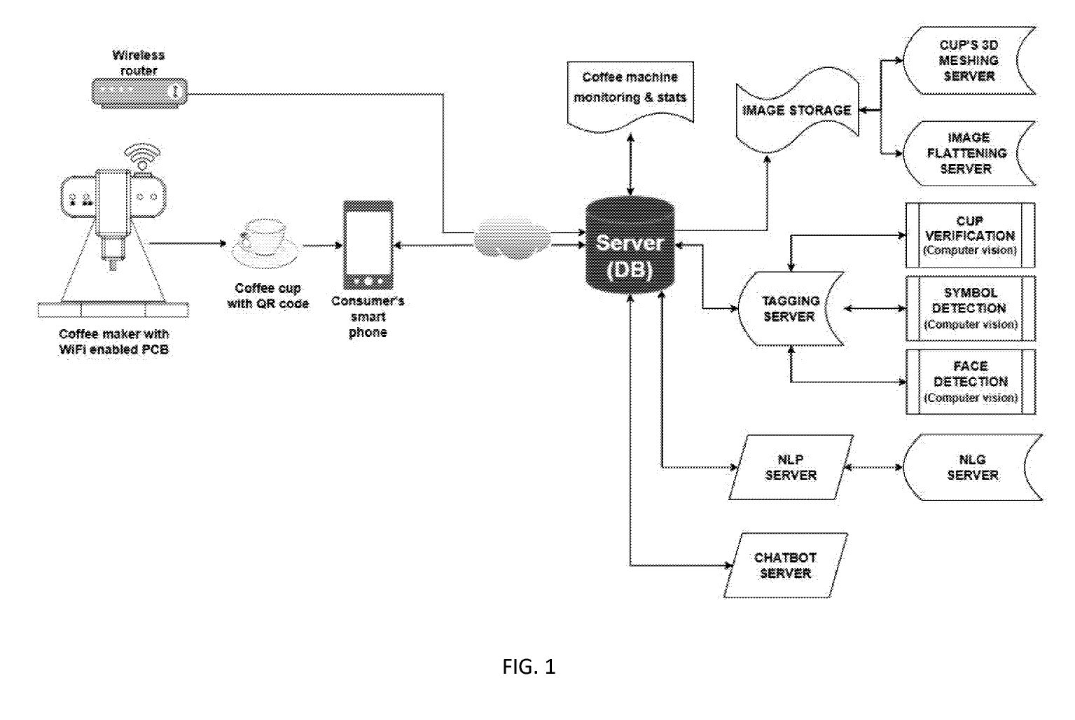

FIG. 2: Schematic view of the Turkish coffee maker and integrated circuit board.

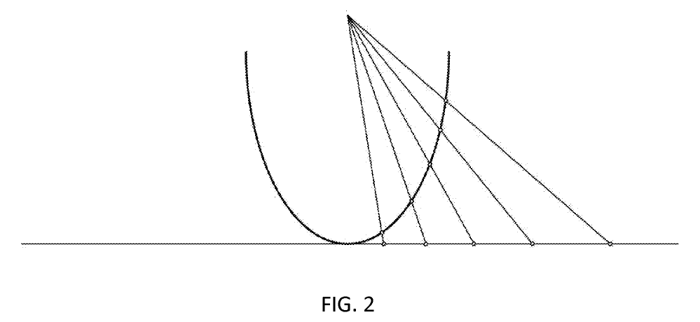

FIG. 3: Schematic view of a coffee cup with QR code.

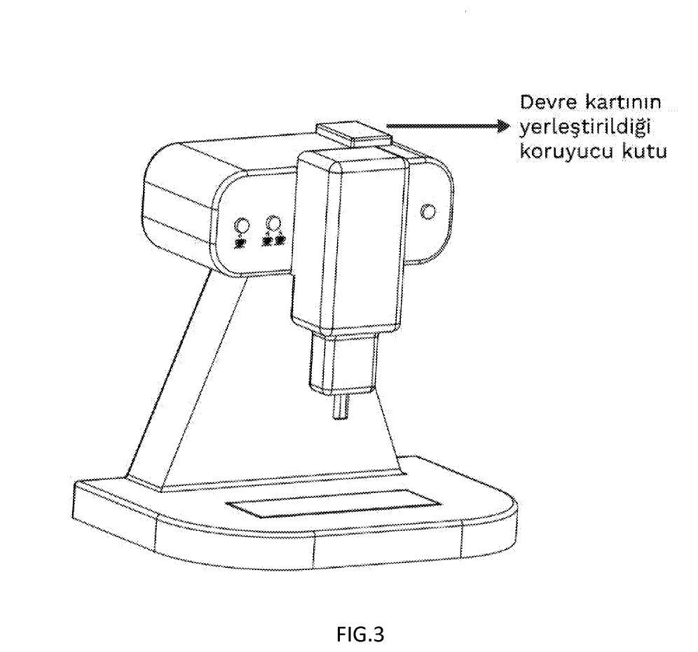

FIG. 4: Flattened image of coffee grounds obtained via stereographic projection.

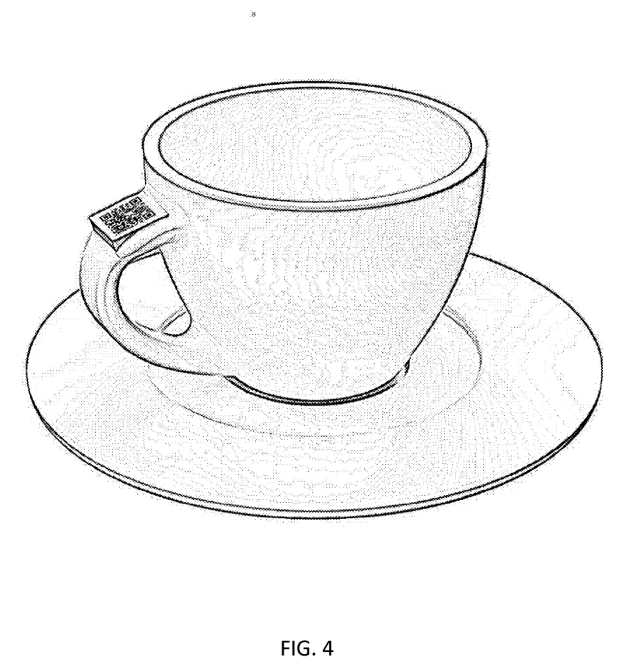

### DETAILED DESCRIPTION OF THE INVENTION

The invention comprises a Turkish coffee maker (1) equipped with a custom circuit board (3). The circuit board records the quantity and timestamp of coffee preparation events and transmits this data to a server (2) via Wi-Fi.

Custom-designed coffee cups (4) contain unique QR codes (4.1) on their handles. Each code is registered in association with the coffee maker and venue. Coffee prepared using the system must be served in these cups.

When a user finishes consuming coffee, the cup is inverted to allow coffee grounds to settle. Once cooled, the user scans the QR code (4.1) with a smartphone (5) to initiate a fortune-telling session. The smartphone connects to the server through a chatbot interface.

The chatbot guides the user to upload an overhead photograph of the cup, including both coffee grounds and QR code, and a selfie. Relationship status information is also collected. The server verifies the QR code from the uploaded image using Al-based computer vision. If

verification fails, the session terminates. If successful, the system constructs a 3D digital model of the cup and grounds using stereographic projection. The flattened image is analyzed with computer vision (including MPEG- 7 Shape Matching) to detect abstract patterns and symbols. Concurrently, the selfie is analyzed to determine demographic and emotional profile data.

All extracted tags are processed by a Natural Language Processing (NLP) engine, which matches detected patterns with meanings in a tasseography database and generates a personalized fortune text. The text is stored, optionally translated, and delivered to the user via the chatbot.

1. 1. A system for providing tasseography-based fortune-telling using Turkish coffee, comprising: a Turkish coffee maker having an integrated circuit board configured to record preparation data of each brewed coffee and transmit said data to a remote server via a network connection; a coffee cup having a handle with a unique machine-readable code; a mobile device configured to scan the machine-readable code and communicate with the server; the server comprising: an image-processing module configured to receive an image of the coffee grounds in the cup and verify the machine-readable code, an artificial intelligence module configured to generate a digital representation of the coffee grounds using stereographic projection and computer vision, a natural language processing module configured to generate a personalized fortune-telling text based on patterns detected in the coffee grounds and user profile data, and an interface configured to deliver the generated fortune text to the mobile device.

2. 12. A method for providing tasseography-based fortune-telling using Turkish coffee, the method comprising: brewing a Turkish coffee using a coffee maker having an integrated circuit board; recording and transmitting preparation data of the coffee to a server; serving the coffee in a cup having a unique machine-readable code; scanning the code with a mobile device to initiate a fortune-telling session; receiving, at the server, an image of the cup containing coffee grounds;
verifying the code to confirm authenticity of the cup and coffee maker; processing the image to detect symbols and patterns in the coffee grounds; generating a fortune-telling text using a natural language processing module based on the detected patterns and user profile data; and transmitting the generated text to the mobile device.

3. 20. A non-transitory computer-readable medium storing instructions that, when executed by one or more processors, cause a system to: receive coffee preparation data from a coffee maker; receive an image of a cup with coffee grounds and a machine-readable code; verify the authenticity of the code; generate a three-dimensional digital model of the cup and flatten the model using stereographic projection; detect symbols and patterns within the flattened image using computer vision; associate the detected patterns with meanings stored in a tasseography database; and output a personalized fortune text via a chatbot interface on a mobile device.

4. 2. The system of claim 1, wherein the circuit board comprises a Wi-Fi module configured to transmit preparation data including timestamps.

5. 3. The system of claim 1, wherein the image-processing module employs MPEG-7 Shape Matching to identify patterns.

6. 4. The system of claim 1, wherein the artificial intelligence module further analyzes a selfie image of the user to determine demographic and emotional profile data.

7. 5. The system of claim 1, wherein the natural language processing module translates the generated fortune text into a language selected by the user.

8. 6. The method of claim 12, further comprising storing detected patterns and generated texts in association with user profiles on the server.

9. 7. The method of claim 12, wherein verifying the code comprises scanning the image of the cup to confirm that the coffee was brewed using the designated system coffee maker.

10. 8. The computer-readable medium of claim 20, wherein the instructions further cause the system to generate a user interface prompting the user for relationship status and incorporating said status into the fortune-telling text.
